(19) United States
(12) Patent Application Publication
(10) Pub. No.: US 2018/0292335 A1
(43) Pub. Date: Oct. 11, 2018

(54) A FOODSTUFF ITEM CHARACTERISTIC MRI DETECTION SYSTEM

(71) Applicant: MM (UK) Limited, Chatteris, Cambridgeshire (GB)

(72) Inventors: Andrew John Patman, Long Bennington, Newark, Nottinghamshire (GB); Xiaodong Li, Long Bennington, Newark Nottinghamshire (GB); Jeremy Roger Jean-Baptist Oden, Long Bennington, Newark, Nottinghamshire (GB); Trevor Francis Bean, Long Bennington, Newark, Nottinghamshire (GB); Christopher Stewart Roberts, Long Bennington, Newark, Nottinghamshire (US)

(21) Appl. No.: 15/767,169

(22) PCT Filed: Oct. 12, 2016
(86) PCT No.: PCT/GB2016/053156

§ 371 Date: Apr. 10, 2018

(30) Foreign Application Priority Data
Oct. 12, 2015 (GB) 1518039.1
Oct. 12, 2015 (GB) 1518040.9

(51) Int. Cl. G01N 24/08; G01R 33/30; G01R 33/56; G01R 33/383; G01R 33/44; G01R 33/483

(52) U.S. Cl. CPC G01N 24/08; G01R 33/307; G01R 33/5608; A23N 15/00; G01R 33/448; G01R 33/4835; G01R 33/383

(57) ABSTRACT

A foodstuff item characteristic detection system (10) comprising: a magnetic resonance imaging, MRI, apparatus (12); a conveyor (14,16,18) for conveying a plurality of foodstuff items (11) such that the foodstuff items are imaged by the MRI apparatus (12) to produce MRI image data; and a computer configured to process the process the MRI image data to enhance the image data such that a predetermined foodstuff item characteristic is identifiable. The system (10) is configured such that, in use, a plurality of foodstuff items (11) are conveyed by the conveyor (14,16,18) such that all of the foodstuff items (11) are imaged by the MRI apparatus (12) to produce MRI image data and the MRI image data is processed by the computer to enhance the MRI image data such that the predetermined foodstuff item characteristic is identifiable.

### FIELD OF THE INVENTION

The present invention relates to a foodstuff item characteristic detection system and, in particular, a fruit characteristic detection system.

### BACKGROUND OF THE INVENTION

Consumers enjoy fruit and, in particular, citrus fruit or soft citrus such as mandarins, satsumas and oranges that do not contain any pips. It is therefore desirable to be able to non-destructively select fruit that does not have pips to provide to consumers. To supply high-volume retailers such as supermarkets with pip-free fruit it is desirable to carry out this non-destructive testing of fruit at very high speed, such as at a rate of 350 fruit per minute, which is around 6 fruit per second. This is the typical speed at which fruit needs to be processed by fruit suppliers supplying fruit to supermarkets. These are very demanding criteria.

Consumers generally prefer sweeter fruit. It is desirable for fruit suppliers to be able to non-destructively select fruit at these very high speeds of relatively high sugar content to provide to supermarkets.

Many approaches have been disclosed in the prior art for non-destructively assessing the quality of fruit.

The main approach has been to use optical techniques, for example, lasers or light emitting diodes (LEDs). For example, US patent application with publication No. US2015-021478 (Daesung Tech Co Ltd) and U.S. Pat. No. 5,708,271 (Sumitomo Metal Mining Co) disclose measuring sugar content in fruit using an LED source; and U.S. Pat. No. 6,504,154 (Sumitomo Metal Mining Co) discloses the use of laser beams to non-destructively measure sugar content. Japanese patent application with publication No. JP H09-196869 (Kobe Steel Ltd) discloses non-destructively measuring the ripeness of a melon and, in particular, sugar content using a nuclear magnetic resonance (NMR) method.

NMR has also been disclosed as used to judge the existence of seeds in fruit on the basis of weight and NMR signal in Japanese patent application with publication No. JP H09-127029 (Mitsubishi Heavy Industry).

NMR and magnetic resonance imaging (MRI) in combination is known to detect pips in oranges. For example, chapter 6 of ‘Process Analytical Technology for the Food Industry’ by O'Donnell, Fagan and Cullen, Springer-Verlag New York, ISBN 978-1-4939-0310-8 describes an arrangement used to detect pips within oranges using a combination of NMR and MRI and image processing. The arrangement uses a 1 tesla (T) magnetic field to image three oranges simultaneously through measurement of their phase-encoded NMR signal. In addition to imaging, the arrangement also measures the T2 relaxation of each fruit and correlates this value to the volume of freeze damage within. T2 is the spin-spin or transverse relaxation time. It is the time constant for loss of phase coherence among spins oriented at an angle to a static magnetic field due to interactions between the spins. No further technical information is explicitly given although example images provided in the text suggest a minimum resolution of the order of 1 mm by 1 mm pixels. However, while this disclosure describes the imaging of three oranges simultaneously, significantly there is no disclosure or even suggestion as to how these three oranges may be imaged at a rapid rate. Low throughput would appear to render this approach unsuitable for use in a factory setting as described above.

Also, in this chapter a magnetic resonance imaging system is described that is coupled to a fruit conveyor for detecting seeds in citrus fruit. An MRI image of a clementine with two seeds is shown with high resolution. Such a high resolution image would be slow to obtain and thus the throughput of fruit on the conveyor through the MRI system would be slow or only some clementines could be imaged on a high throughput arrangement.

The NMR techniques (without using MRI) produce a nuclear magnetic resonance signal across a whole sample fruit. In the arrangements described in the prior art, it is very slow to obtain an adequate NMR signal. MRI produces images of a sample including its interior in two-dimensional slices of a three-dimensional sample. NMR and indeed MRI are intrinsically low signal-to-noise processes. The disclosed techniques are inadequate for assessing fruit at the high speeds required of a modern fruit processing plant as described above.

The optical techniques described do not provide the ability to assess the presence of pips in citrus fruit at the high speeds required of a modern fruit processing plant as described above.

### BRIEF SUMMARY OF THE INVENTION

The inventors of the present application have appreciated that one or more characteristic of a foodstuff in the form of fruit and, in particular, citrus fruit or soft citrus such as mandarins, satsumas and oranges may be automatically tested very rapidly using a combination of low-resolution magnetic resonance imaging (MRI) and computerised processing of image data from a low-resolution MRI image of the fruit to enhance or improve the image of the fruit rapidly transported through an MRI scanner on a conveyor. This is very surprising as MRI is an intrinsically low signal-to-noise imaging process that is considered very slow. The inventors of the present application have appreciated that each and every fruit on the conveyor travelling at a rate of more than 200 fruit per minute, such as more than 300 fruit per minute, substantially 350 fruit per minute or 350 fruit per minute may be automatically tested using this method to assess one or more characteristic of the fruit.

Embodiments of the present invention provide a fruit characteristic detection system in the form of a fruit pip detection system that greatly increases the throughput of the scanning. A fruit characteristic in the form of Brix or sugar content measurement and/or measurement of other chemical components of the fruit may also be provided at a throughput range that is commercially viable for use within a fruit factory.

The invention in its various aspects is defined in the independent claims below to which reference should now be made. Advantageous features are set forth in the dependent claims.

Embodiments of the foodstuff item or fruit characteristic detection system described herein identify the presence of a predetermined foodstuff item characteristic in the form of pips within fruit, particularly satsumas, mandarins and oranges, by generating MRI images through the foodstuff item (fruit) and then applying imaging processing algorithms to enhance or improve relevant portions of the image such that a predetermined foodstuff item characteristic (or pips) is identifiable and then perform an automated detection process of the food item characteristic. Typically, the unenhanced image of low resolution will show a slight change in image contrast between large image blocks or pixels due to the presence of a pip. However, this, in itself, is not identifiable with certainty as a pip. However, the image processing algorithm enhances the contrast in a particular way such that the presence of a pip is identifiable. The characteristic T2 relaxation time of each orange may also be measured using a known Carr Purcell Meiboom Gill (CPMG) echo-train sequence, and this value is used to determine the individual Brix level of a fruit. Alternatively or additionally, a computer of the foodstuff item detection system may be configured to detect chemical composition such as at least one predetermined chemical species.

Embodiments of the fruit characteristic detection system described herein differ from known arrangements by providing very rapid imaging or high fruit throughput such as 350 mandarins, satsumas or oranges per minute. This is achieved through a combination of techniques and approaches that is contrary to known MRI acquisition. Firstly, the images produced are of much lower resolution than normal such as required for medical diagnostic imaging (for example, an MRI image of greater than between 0.5 mm to 2 mm by 0.5 mm to 2 mm or 1 mm by 1 mm pixels). An MRI image is that derived directly from an MRI apparatus or spectrometer. An MRI image is an image that has not been image processed such as to enhance the image. By using low resolution MRI images, the number of time-consuming phase encoding steps throughout the image acquisition process is low. The routines or image processing employed to undertake the pip detection process are based on machine learning algorithms. These are specifically trained to identify pips within the coarse images generated.

In addition, embodiments of the MRI apparatus of the fruit characteristic detection system use a bespoke radio frequency (RF) transceiver coil assembly that allows the imaging of a plurality of fruit, such as six oranges, simultaneously within one homogeneous volume of applied magnetic field. This array and its design provides for parallel imaging techniques to be incorporated into the data collection process. As such, the number of phase encoding steps may again be reduced and the imaging rate accelerated accordingly. This process allows several slices to be imaged through each fruit without impact on the acquisition time. Multiple slices are required by the image processing software to accurately determine if pips are present throughout the entire volume of each orange.

It has been appreciated that a further reduction in image acquisition time is achieved using so-called ‘half-Fourier’ k-space population strategies. These schemes use the inherent symmetry of the k-space domain to replicate data values instead of measuring them directly. As a result, a reduced number of data collections can yield the same quantity of imaging information. This directly reduces the imaging time required.

In embodiments of the present invention, T2 relaxation time of each individual fruit is measured simultaneously using a CPMG echotrain sequence. This takes place after imaging has been completed. Again, this is made possible by the specific construction of the RF coil array.

Both the hardware and software may analyse the resulting images and relaxation values to maximise processing speed. No additional or parallel NMR data is required.

Arrangements are described in more detail below and take the form of a foodstuff item characteristic detection system comprising: a magnetic resonance imaging, MRI, apparatus; a conveyor for conveying a plurality of foodstuff items such that the foodstuff items are imaged by the MRI apparatus to produce MRI image data; and a computer configured to process the MRI image data to enhance the image data such that a predetermined foodstuff item characteristic is identifiable. The system is configured such that, in use, a plurality of foodstuff items are conveyed by the conveyor such that the foodstuff items are imaged by the MRI apparatus to produce MRI image data and the MRI image data is processed by the computer to enhance the MRI image data such that the predetermined foodstuff item characteristic is identifiable.

A foodstuff characteristic detection method may be provided, the method comprising: a conveyor conveying a plurality of foodstuff items such that the foodstuff items are imaged by an MRI apparatus; a computer processing image data from the MRI apparatus to enhance the image data to produce enhanced image data such that a predetermined foodstuff item characteristic is identifiable; and the computer detecting the predetermined food stuff item characteristic of the foodstuff items using the enhanced image data. A computer program for controlling the method may be provided. A computer-readable medium comprising instructions for controlling the method may be provided. The computer-readable medium may comprise, for example, a CD-ROM, DVD-ROM, hard disk drive or solid state memory such as a USB (universal serial bus) memory stick.

### BRIEF DESCRIPTION OF THE DRAWINGS

The invention will be described in more detail, by way of example, with reference to the accompanying drawings, in which:

FIG. 1 is a perspective view from above of a fruit pip detection system embodying an aspect of the present invention;

FIG. 2 is a perspective view from a side of the fruit pip detection system of FIG. 1;

FIG. 3 is a plan view of the fruit pip detection system of FIGS. 1 and 2;

FIG. 4a is a schematic plan view of fruit in a container for use in the fruit pip detection system embodying an aspect of the present invention;

FIG. 4b is a schematic cross section viewed from the side of the fruit and container of FIG. 4a;

FIG. 5 is a schematic perspective view of the fruit and container of FIGS. 4a and 4b in the fruit pip detection system embodying an aspect of the present invention; and

FIG. 6 is a flow diagram illustrating the operation of the fruit pip detection system embodying an aspect of the present invention.

### DETAILED DESCRIPTION OF THE INVENTION

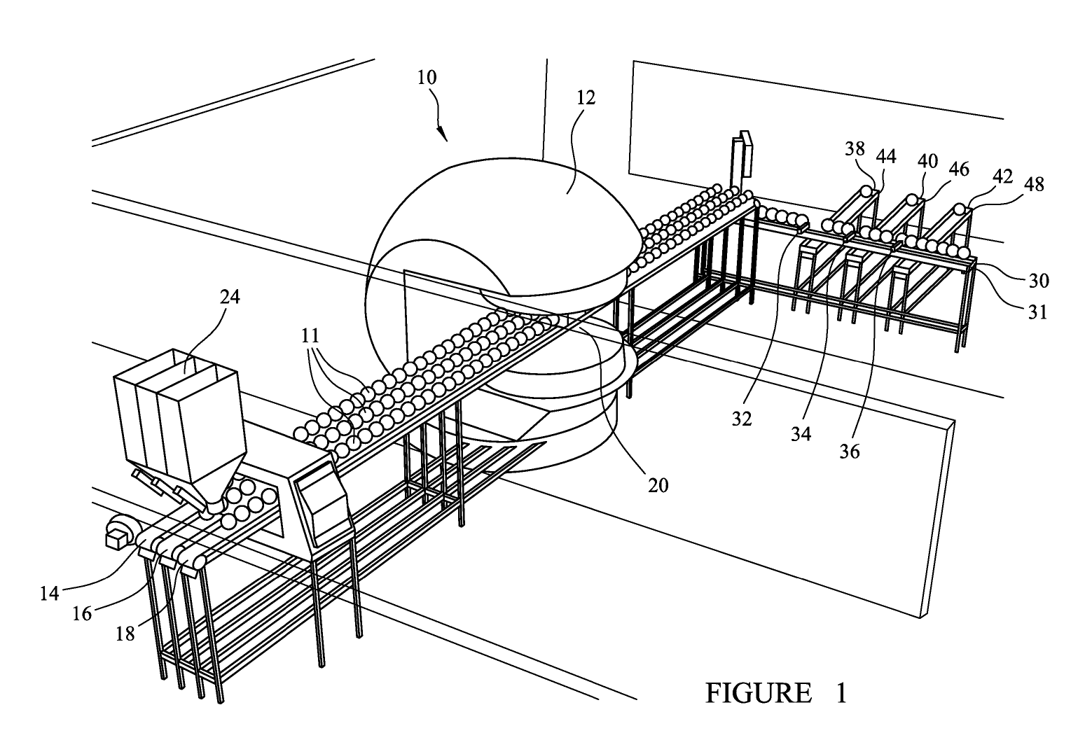

An example foodstuff characteristic detection system in the form of a fruit characteristic detection system, in this example, a fruit pip detection system 10 will now be described with reference to FIGS. 1 to 3. In this example, each fruit is an orange 11. The arrangement may be used for other fruit such as other citrus fruit, soft citrus and, in particular, satsumas and mandarins.

The fruit pip detection system 10 comprises a single MRI scanner or apparatus 12 through which three individual polytetrafluoroethylene (PTFE) conveyors 1 or conveyor systems 14, 16, 18 pass side-by-side to one another. The conveyors are in the main made from PTFE. The conveyors may alternatively or additionally include one or more of: foodstuff safety approved material, non-hygroscopic material, material that does not resonant at an operating frequency range of the MRI apparatus and/or material that provides a low nuclear magnetic resonance signal.

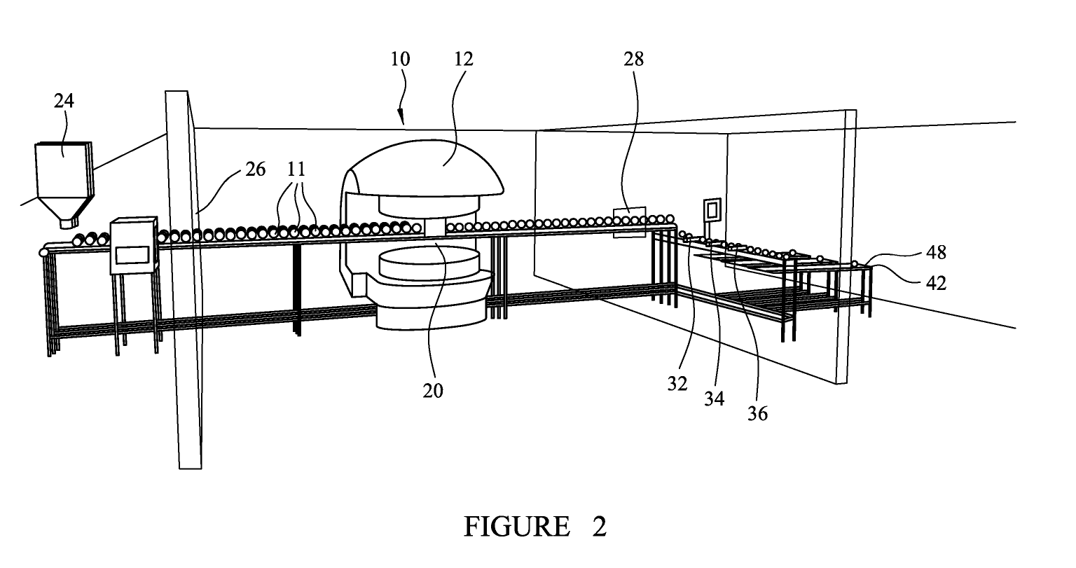

A pair of oranges 11 of each conveyor is briefly stopped within the MRI scanner to be imaged in a scan region 20 (shown best in FIG. 2). In other words, six oranges enter the homogeneous magnetic volume of the scanner at one time for imaging. A bespoke RF transceiver array (not illustrated in the Figures), comprising six individual transmit and receive coils in a 2×3 arrangement, is located within the scanner. Each of the three lines or conveyors pass through two of the coils in series.

The MRI scanner 12 is a single, c-shape permanent magnet with a field strength of 1 T (the field strength may be, for example, between 0.4 T and 2 T, or between 0.6 T and 1.5 T). This is sized or arranged to provide the homogeneous volume required for imaging of six oranges 11 taking into account additional homogeneity that may be generated by additional shim coils.

During each scan cycle, six oranges 11 enter the MRI scanner 12 such that each orange is in alignment with one of the coils. The movement of the lines or conveyors 14, 16, 18 is indexed in order to allow the oranges to remain stationary throughout the duration of the process. Once in place, the MRI scanner, uses a bespoke fast-spin-echo excitation/phase encoding pulse sequence to produce a plurality or several cross-sectional images through each of the fruit individually. Alternatively, a gradient echo sequence may be used. The design and hardware of the transceiver array provides for acceleration of the imaging process through parallel imaging and the simultaneous acquisition of all slices. The rate of data collection is increased through the application of so-called ‘half-Fourier’ k-space sampling strategies in which only part or a partial sample of k-space is taken, typically slightly more than half. In this example, there is a nominal 60% data acquisition, with the remaining points being generated according to the (largely) symmetric nature of the k-space domain. After imaging, a secondary series of RF excitations is used to generate a characteristic CPMG echo train for each of the six fruit individually.

With the collection of all of the necessary data, the scanned fruit or oranges 11 is moved out of the MRI scanner 12 by the conveyors 14, 16, 18. Indexing of the lines' motion thus permits the next six oranges to enter for analysis.

Each of the images obtained for the six scanned fruit or oranges 11 is then enhanced and evaluated using bespoke recognition software on a computer (not shown). Machine learning algorithms employed detect the presence of pips within the enhanced images characteristic of the MRI scanner 12 (i.e. under continuous contrast weighting, resolution and aspect ratio). Should a pip be detected, the position of the target or identified orange on the indexed line is tagged within the software of the computer for mechanical rejection at a later point (discussed below).

A secondary computational analysis by the computer performs a least squares regression analysis on the T2 relaxation curve of each orange 11 in order to determine its characteristic decay constant. This is undertaken in parallel with that of the image evaluation routine described above in order to minimise processing time. With the constant known, this value is compared to a pre-determined calibration curve to yield the respective Brix level or sugar level in each case. Again, the software running on the computer assigns the measured Brix value to the position of the associated orange for mechanical rejection at a later point (discussed below).

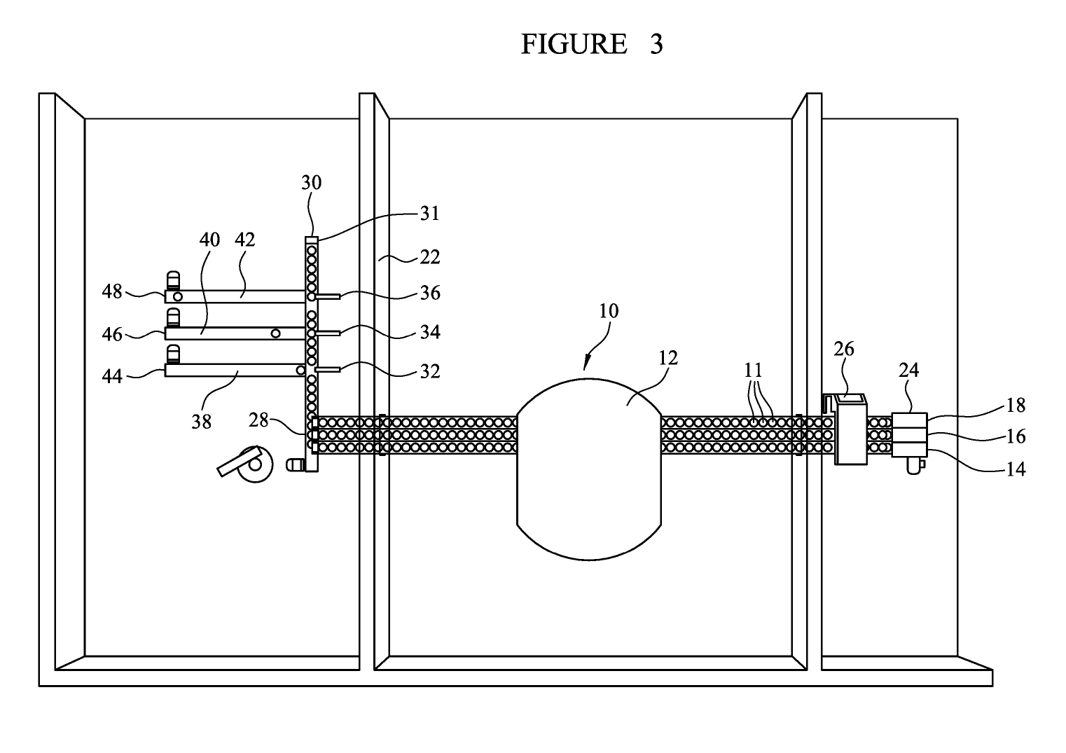

The MRI scanner, unit or apparatus 12 is housed in a dedicated, copper lined cabin 22 (shown best in FIG. 3) for safety purposes and to mitigate against unwanted radio frequency (RF) noise ingress. Fruit is loaded onto one of the three lines or conveyors 14, 16, 18 prior to entering the cabin through the use of hoppers and vibrating loader mechanisms 24. Waveguides 26,28 (shown best in FIG. 3) surrounding the lines as they enter and exit the cabin ensure that unwanted RF radiation does not enter through the openings in the front and rear walls.

In this way, all of the pieces of fruit travelling on the conveyors 14, 16, 18 at very high speed are imaged by the MRI apparatus 12 to produce MRI image data and the MRI image data is processed by the computer to provide for fruit characteristic detection of all of the pieces of fruit.

After exiting the conveyors 14, 16, 18, outside the cabin 22, all fruit 11 enters onto another line or conveyor 30 in single file. The exit 31 of this conveyor is for acceptable high quality fruit for packing. Given the accuracy of the system, a 100% certainty of the high quality of the fruit can be given. While the fruit travel along on this conveyor, the fruit pass in front of pneumatic pistons 32,34,36 that push selected oranges, as selected or identified by the computer discussed above if they have pips or a Brix level below a predetermined level, onto further, perpendicular lines or conveyors 38,40,42 respectively according to the required segregation in Brix level and pips. These conveyors are for fruit of lower quality, for example with pips or low Brix level. Fruit at the exits 44,46,48 of these conveyors may be for packing, disposal or other uses.

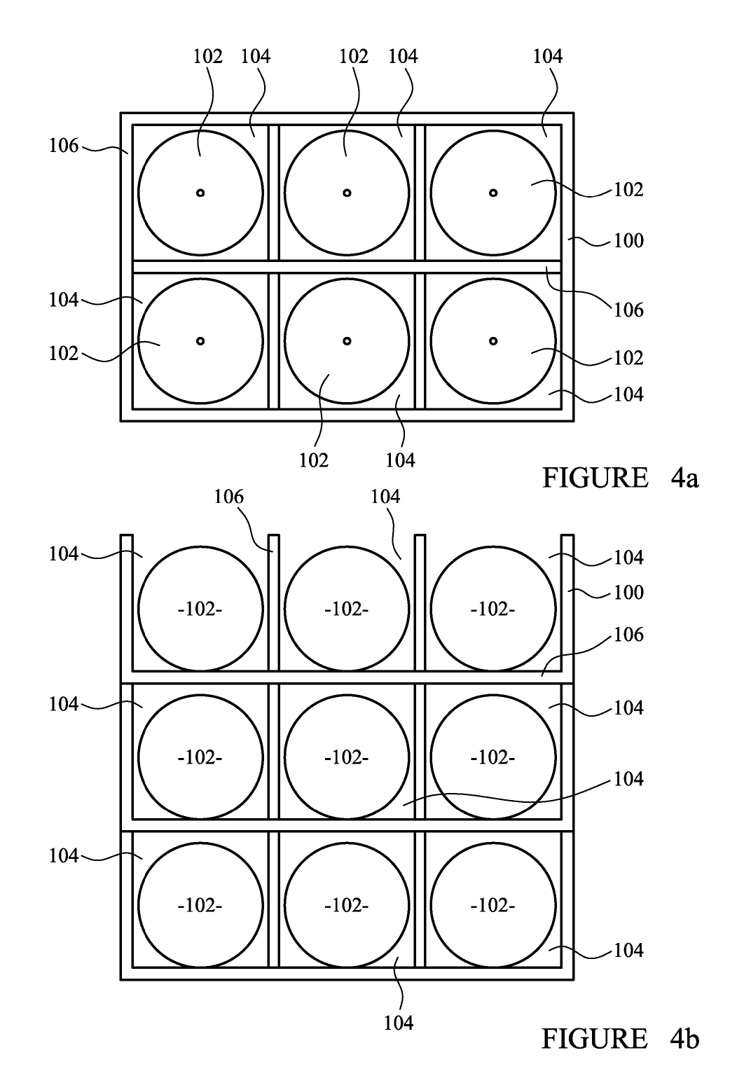

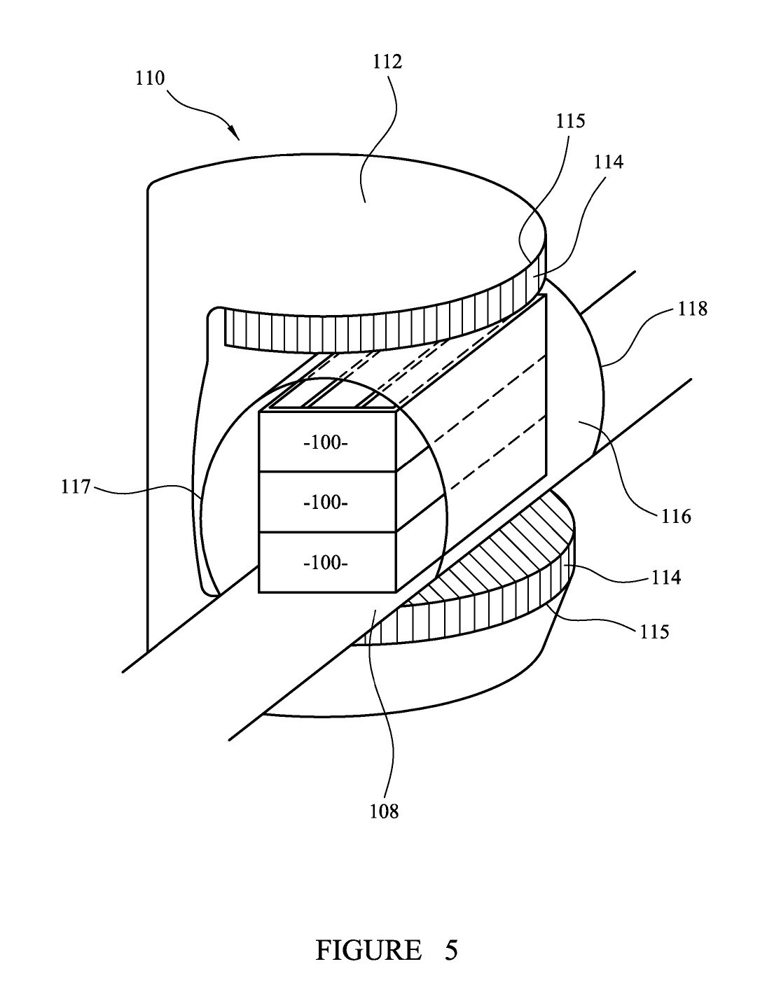

In another example foodstuff characteristic detection system in the form of a fruit characteristic detection system, the fruits are provided to the MRI scanner in one or more containers. This is illustrated in FIGS. 4a, 4b and 5, which illustrate components forming part of a fruit pip detection system.

Referring first to FIGS. 4a and 4b, in this example, three containers or boxes 100 are provided simultaneously to an MRI apparatus. The containers are each the same. They are stacked one on top of the other. Altogether, 18 fruits 102, in this example, oranges but other citrus fruit may be provided, are located in the containers imaged by the MRI apparatus simultaneously, with six fruit in each of the three containers. The six fruit are arranged two transversally and three longitudinally. Each container is made from MRI-invisible material, in this example, PTFE, which advantageously is also food-safe. Each container includes a compartment 104 for each fruit. The compartments are sized to fit the largest size of fruit to be imaged. In this example, the compartments are square shape with a side length of 10 cm. There are walls or partitions 106 of the MRI-invisible material between the fruits (in FIGS. 4a and 4b only some of the walls have reference numerals beside them for clarity). In other words, the fruits are separated by MRI-invisible material. Advantageously, by separating the fruit with MRI-invisible walls, good contrast is provided between fruits and this aids in identifying the fruit from an MRI image. Each of the containers has locking or interlocking features around an upper and lower outer rim (not illustrated in the Figures) to lock with another container both above and below. In this way, the position of each container is interchangeable and they can be readily reused in the system. Together, each stack of containers has a height of 35 cm.

As illustrated in FIG. 5, in use, each stack of three containers 100 is located on a conveyor 108 and each stack of containers passes through the MRI apparatus 110 in turn at high speed. In this way, a plurality of foodstuff items can be imaged simultaneously in different horizontal and/or vertical positions. Each stack of containers is held briefly inside the MRI apparatus while it is imaged. In this example, for three seconds per stack of containers.

The MRI apparatus 110 includes a yoke 112. The yoke is a frame, in this example, with a U shape cross section, to which permanent magnets 114 are attached at each of its free ends 115. This arrangement provides the magnetic field through the fruit to be imaged. Shimming coils are provided that maintain the magnetic field homogeneity within required limits. The permanent magnet design together with the shimming coils provides sufficient homogeneous imaging volume to encompass the fruit being imaged.

Waveguides (not shown) are provided at the entrance 117 and exit 118 of the MRI apparatus 110 that are configured to attenuate external electromagnetic (EM) noise. Advantageously, these also act as mechanical guards.

The MRI apparatus 110 includes a bespoke phased-array transceiver coil 116 located in the homogeneous magnetic field provided by the magnet and shimming coils in which the fruit is held to be imaged. This coil provides a unique spatial sensitivity profile to increase data collection rate for the plurality of fruits (each fruit cluster). Effectively, the single coil acts like a plurality of coils with each of the coils for imaging each of the fruit in the homogeneous magnetic field. In other words, each of the fruit in the stack of containers. Furthermore, measurement of signal intensity as a function of T2 relaxation or magnetisation is provided for individual fruit despite scanning all fruit together. As is known in the art, T2 relaxation is where protons become out of phase or, in other words, become desynchronized. As a result, there is a decay of transverse magnetization.

A tailored multi-slice multi-echo pulse sequence is used by the MRI apparatus 110 to achieve a required number of slices quasi-simultaneously. The size and number of slices is selected, in this example, such that not the whole of each fruit is imaged. Indeed, significantly less than the whole of each fruit is imaged. The size and number of slices are selected such that any gaps or not imaged portions are not bigger than an estimated smallest dimension of a pip (or other feature) that the system is attempting to identify. In this example, 15 image slices are obtained in the form of 5 slices for each of the 3 layers of fruit. The thickness or width of each slice is significant. It is selected as a typical dimension of a pip (target feature to be imaged and then identified), and is very wide, in this example, 10 mm (but may be between 5 mm and 15 mm). This is significant because as a result very low image resolution is provided. This reduces MRI imaging time without, as the inventors of the present application have appreciated, loss of information to identify pips provided computerized image processing to enhance the images is carried out. In other words, only or substantially only the information required to accurately determine the presence of a target feature (a pip) is sought and collected.

The field of view and k-space sampling frequencies (k-space is the Fourier transform of the magnetic resonance image obtained) are selected to achieve sufficient image resolution across each slice of imaged volume whilst maintaining high scanning rate. A k-space fill pattern is used to provide a fast imaging speed at the expense of image resolution. In other words, provide an intentionally coarse image resolution. The inventors of the present patent application have appreciated that the degradation of image resolution is not too great as to prevent a target feature (a pip) from being identified following subsequent image processing to enhance the image as explained in more detail below. This is counterintuitive as one would generally attempt to obtain the best image resolution.

Each of the images obtained from the scanned fruit or oranges is then enhanced and evaluated using bespoke recognition software on a computer (not shown).

Broadly, the image analysis software installed on the computer carries out the following steps.

Raw data from 15 image slices (3 layers of 5 slices) as described above obtained by the MRI apparatus are retrieved or input into the computer. An inverse Fourier transform is applied to convert this k-space data to an image of each slice. An image of each of the slices of each orange are processed in parallel in order to detect the position of each orange. This is an optional step, and can be used to provide a size of each orange. The slices of each orange are then processed to detect one or more pips as follows.

Noise is removed using known techniques, for example, filters and morphological operations. Smart thresholding is then applied to separate potential pips or pip candidates from the background. In other words, for example, if the intensity of a predetermined number of image pixels are above a predetermined threshold intensity then they are flagged as a potential pip candidate. This may be used in combination with other techniques such as distance transform, for instance. Image segmentation is then carried out including contour detection and filtering, for example, to filter contours by size. Optionally, contour shapes are determined in order to confirm that the candidates are one or more pips.

Finally, individual slices are merged in order to determine which oranges have one or more pip. Oranges identified as having one or more pip are labelled accordingly.

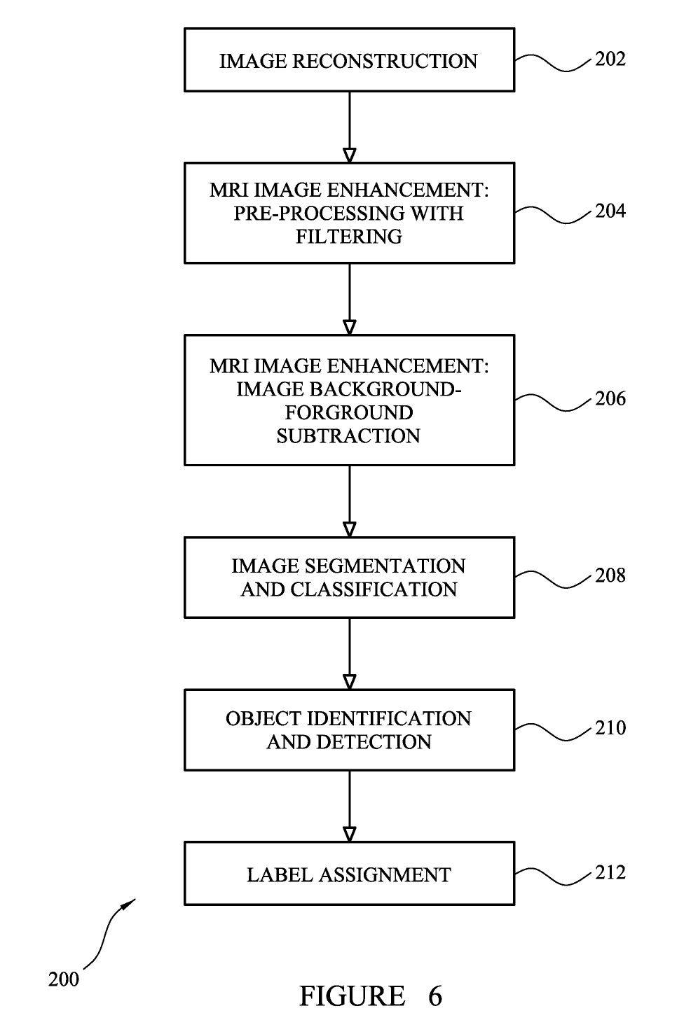

In more detail, the steps of the image processing for orange pip detection from an MRI apparatus are as follows and are illustrated in the flow diagram 200 of FIG. 6. They are implemented in software or as a computer program installed on the computer. The steps may be carried out on a general purpose processor of the computer or advantageously on a graphics processing unit (GPU) of the computer which provides fast processing. The computer program or instructions may be provided on a non-transitory computer-readable medium. The computer-readable medium may comprise, for example, a CD-ROM, DVD-ROM, hard disk drive or solid state memory such as a USB (universal serial bus) memory stick.

Firstly, an image is reconstructed from the MRI image (step 202) by the processor of the computer. Raw data from the MRI apparatus in the form of digitized echo signal from magnetic resonance reflection in multiple slices of k-space data is received or input at the computer. The raw data is in a certain format, in this example, DICOM (Digital Imaging and Communications in Medicine) format. The data represents an optimal section of a slice of the fruit being imaged. The data is decoded by the processor of the computer into a particular data structure in the form of a data matrix. A Fourier transform is applied by the processor of the computer on the data matrix and this reconstructs an image of the fruit in the red-green-blue colour model (RGB) or greyscale.

This RGB or greyscale image is then pre-processed with filtering (step 204) by the processor of the computer. The initial images obtained as described above may include noise or other artefacts including blurred or confusing images. Serial filters are applied by the processor of the computer such as a Gaussian filter, a median filter, histogram equalization, entropy filter, box filter, low-pass and/or high-pass (the latter two together remove so-called salt and pepper noise). One or more of these filtering techniques are used to enhance the MRI image data such as to improve the contrast and/or sharpness of the image.

Image background and foreground subtraction is then carried out by the processor of the computer to further enhance the MRI image data (step 206). Front and back images are separated by the processor of the computer operating on pixel levels by carrying out Gaussian filtering, statistical filtering, Gaussian mixture modelling and/or bitwise-operations. In this way, overall background images are eliminated from the images.

Image segmentation and classification are then carried out by the processor of the computer (step 208). Classification is carried out based on comparison to a predetermined calibration model. The model is calibrated by pre-imaging many candidate fruit (in the order of 100s of candidates), typically by using a much longer, higher resolution MRI imaging technique than used in the foodstuff characteristic detection system. Areas or segments potentially including pips are then identified from the resulting images by using one or more cluster analysis techniques or other machine learning techniques such as, for example, k-means clustering, fixed thresholding, adaptive thresholding, or statistical analysis based on the calibration model to form binary images.

Identification and detection of objects is then carried out by the processor of the computer (step 210). Morphological operation and/or un-supervised learning are provided to smooth dim or isolated distinctive small spots to highlight distinctive images to improve pip identification accuracy. This is, in effect, further enhancement of the MRI image data. Hole filling and boundary removing is then carried out. Finally, area calculation is then used to identify one or more pip. In this way, enhanced image data is processed by the computer to detect at least one pip.

A label is then applied to a fruit that is identified as having one or more pip by the processor of the computer (step 212). These labels identify an individual fruit or pip for display, tracking, monitoring, and operation of the conveyor so that the fruit with one or more pips can be appropriately handled by the conveyor such as to direct fruit with one or more pips down one route and fruit with no pips along another route.

Embodiments of the present invention have been described. It will be appreciated that variations and modifications may be made to the described embodiments within the scope of the present invention.

1. A foodstuff characteristic detection system, the system comprising;
a magnetic resonance imaging, MRI, apparatus;
a conveyor for conveying foodstuff items such that the foodstuff items are imaged by the MRI apparatus to produce MRI image data; and
a computer configured to process the MRI image data to enhance the image data such that a predetermined foodstuff item characteristic is identifiable;
the system being configured such that, in use, a plurality of foodstuff items are conveyed by the conveyor such that the foodstuff items are imaged by the MRI apparatus to produce MRI image data and the MRI image data is processed by the computer to enhance the MRI image data such that the predetermined foodstuff item characteristic is identifiable.

2. A foodstuff characteristic detection system according to claim 1, wherein the foodstuff items comprise fruit.

3. A foodstuff characteristic detection system according to claim 2, wherein the fruit comprise citrus fruit or soft citrus such as mandarins, satsumas or oranges.

4. A foodstuff characteristic detection system according to claim 1, wherein the predetermined fruit characteristic comprises presence of at least one pip.

5. A foodstuff characteristic detection system according to claim 1, wherein the computer is configured to detect at least one of: sugar level; and chemical composition.

6. (canceled)

7. A foodstuff characteristic detection system according to claim 1, wherein the MRI apparatus comprises a permanent magnet to provide a magnetic field.

8. A foodstuff characteristic detection system according to claim 7, wherein the strength of the magnetic field is between 0.4 tesla and 2 tesla.

9. A foodstuff characteristic detection system according to claim 8, wherein the strength of the magnetic field is between 0.6 tesla and 1.5 tesla.

10. A foodstuff characteristic detection system according to claim 9, wherein the strength of the magnetic field is 1 tesla.

11. (canceled)

12. (canceled)

13. (canceled)

14. (canceled)

15. (canceled)

16. A foodstuff characteristic detection system according to claim 1, wherein the image data from the MRI apparatus has a resolution of between 0.5 mm to 2 mm by 0.5 mm to 2 mm.

17. A foodstuff characteristic detection system according to claim 1, wherein the image data from the MRI apparatus has a resolution of 1 mm by 1 mm or 2 mm by 2 mm.

18. A foodstuff characteristic detection system according to claim 1, wherein the MRI apparatus and the conveyor are configured to image a plurality of foodstuff items simultaneously.

19. (canceled)

20. A foodstuff characteristic detection system according to claim 1, wherein the conveyor is indexed such that a foodstuff item being imaged by the MRI apparatus is stopped in the MRI apparatus for a predetermined time to be imaged.

21. A foodstuff characteristic detection system according to claim 1, wherein the MRI image data is processed by the computer using image processing algorithms to produce enhanced image data.

22. A foodstuff characteristic detection system according to claim 1, wherein the enhanced image data is processed by the computer to detect at least one predetermined foodstuff item characteristic.

23. (canceled)

24. (canceled)

25. (canceled)

26. (canceled)

27. A foodstuff characteristic detection system according to claim 1, configured such that fruit characteristic detection is at a rate of more than 200 fruit per minute, preferably more than 300 fruit per minute, preferably substantially 350 fruit per minute and most preferably at 350 fruit per minute.

28. (canceled)

29. A foodstuff characteristic detection system according to claim 1, wherein foodstuff items are conveyed on the conveyor in containers.

30. A foodstuff characteristic detection system according to claim 1, wherein the containers each comprise or consist of Mitt-invisible material, such as polytetrafluoroethylene.

31. A foodstuff characteristic detection system according to claim 29, wherein the containers each comprise one or more partitions, or walls, wherein each partition or wall separates a plurality of foodstuff items in a container.

32. (canceled)

33. (canceled)

34. A foodstuff characteristic detection method, the method comprising:
a conveyor conveying a plurality of foodstuff items such that the foodstuff items are imaged by an MRI apparatus;
a computer processing image data from the MRI apparatus to enhance the image data to produce enhanced image data such that a predetermined foodstuff item characteristic is identifiable; and
the computer detecting the predetermined foodstuff item characteristic of the foodstuff items using the enhanced image data.

35. (canceled)

36. (canceled)

37. (canceled)
